(19) United States
(12) Patent Application Publication
(10) Pub. No.: US 2026/0092480 A1
(43) Pub. Date: Apr. 2, 2026

(54) LATCH MECHANISM AND NON-EQUILATERAL RECTANGULAR RETICLE CONTAINER HAVING THE SAME

(71) Applicant: Gudeng Precision Industrial Co., Ltd., New Taipei (TW)

(72) Inventors: Ming-Chien Chiu, New Taipei (TW); Chia-Ho Chuang, New Taipei (TW); Hsin-MIn Hsueh, New Taipei (TW); Pin-Cheng Chen, New Taipei (TW); Ya-Shi Wang, New Taipei (TW)

(21) Appl. No.: 19/341,255

(22) Filed: Sep. 26, 2025

Related U.S. Application Data
(60) Provisional application No. 63/702,183, filed on Oct. 2, 2024.

(51) Int. Cl. E05C 9/10; G03F 1/66

(52) U.S. Cl. CPC E05C 9/10; G03F 1/66

(57) ABSTRACT

Provided is a latch mechanism adapted for use in a door of a non-equilateral rectangular reticle container. The latch mechanism includes a driving member disposed at the door, and a plurality of driven assemblies respectively abutting against the driving member. When the driving member rotates, the plurality of driven assemblies are synchronously actuated to undergo reciprocating movement to protrude from or retract into the door, such that at least one of the plurality of driven assemblies is configured to lock or unlock a lateral position on the door of the non-equilateral rectangular reticle container.

### CROSS-REFERENCE TO RELATED APPLICATION

This application claims priority to and benefits of U.S. Provisional Application No. 63/702,183, filed Oct. 2, 2024, the content of which is incorporated by reference herein in its entirety.

### BACKGROUND OF THE INVENTION

### Field of the Invention

The present disclosure relates to latch mechanisms, and more particularly to a latch mechanism for use in a non-equilateral rectangular reticle container.

### Description of the Prior Art

As high-numerical-aperture (High-NA) extreme ultraviolet (EUV) lithography technologies advance, the dimensions of reticles increase. Accordingly, there is a need for reticle containers having larger, non-equilateral rectangular sizes. In existing reticle containers, the latch mechanism operates through engagement of a central cam with a load port, such that rotation of the cam drives two sets of latch mechanisms. As shown in FIG. 10, FIG. 10 illustrates a door 800 of a conventional reticle container. The latch mechanism of the conventional reticle container includes a cam 80 and two latch members 82. Rotation of the cam 80 causes the latch members 82 to protrude from, or retract into, the door 800. The weight of the reticle container increases with its overall size, for example in a 6×12-size reticle container, the existing latch mechanism is insufficient to stably secure the door to the housing. Portions of the door not constrained by the latch mechanism become longer, leading to poor sealing performance, door deformation, or difficulties in opening and closing the reticle container. When applied to large reticle containers, for example, a 6×12-size reticle container, the existing latch mechanism is insufficient to stably secure the door to the housing. Portions of the door not constrained by the latch mechanism become longer, leading to poor sealing performance, door deformation, or difficulties in opening and closing the reticle container.

### SUMMARY OF THE INVENTION

To address the foregoing issues, the disclosure provides a latch mechanism adapted for a non-equilateral rectangular reticle container. The latch mechanism disclosed herein is compatible with existing load ports to eliminate the need for manufacturers to purchase additional equipment. In addition, the latch mechanism improves the sealing performance of non-equilateral rectangular reticle containers.

The disclosure provides a latch mechanism, adapted for a door of a non-equilateral rectangular reticle container, comprising: a driving member disposed at the door; a plurality of driven assemblies respectively abutting against the driving member, wherein, when the driving member rotates, the plurality of driven assemblies are synchronously actuated to undergo reciprocating movement to protrude from or retract into the door, such that at least one of the plurality of driven assemblies is configured to lock or unlock a side of the door of the non-equilateral rectangular reticle container.

In a specific embodiment, the plurality of driven assemblies are configured to lock or unlock long sides of the door of the non-equilateral rectangular reticle container.

In a specific embodiment, the plurality of driven assemblies are respectively disposed on opposite sides of the door and operably coupled to the driving member, and each of the plurality of driven assemblies comprises a driven member and a latch member, the driven member having a connecting rib, one end of the connecting rib connected to the driving member and the other end of the connecting rib connected to the latch member, such that, when the driving member rotates, the driven members are synchronously actuated, allowing the latch members to protrude from or retract into the door.

In a specific embodiment, when the driving member rotates, the driven members are synchronously actuated, allowing the connecting ribs to undergo lateral linear movement and push the latch members to move longitudinally toward the sides of on the door, allowing the latch members to protrude from or retract into the door.

In a specific embodiment, each of the connecting ribs has two opposite inclined surfaces, and the latch members are actuated by the connecting ribs to slide along the inclined surfaces respectively, allowing the latch members to protrude from or retract into a lateral side of the door.

In a specific embodiment, each of the plurality of driven assemblies comprises a connecting rib, at least one long-side latch member, and at least one short-side latch member, one end of the connecting rib connected to the driving member, with the long-side latch member disposed on long sides of the door, and with the short-side latch member disposed on short sides of the door, wherein, when the driving member rotates, the plurality of driven assemblies are synchronously actuated to cause the connecting ribs to undergo lateral linear movement to synchronously push the long-side latch member toward the long sides of the door and the short-side latch member toward the short sides of the door, allowing the long-side latch member and the short-side latch member to protrude from or retract into the door simultaneously.

In a specific embodiment, each of the connecting ribs has two opposite inclined surfaces corresponding in position to the long-side latch members, and ends of the connecting ribs are positioned distal to the driving member and respectively connected to the short-side latch members, and wherein the connecting ribs actuate the long-side latch members to slide along the inclined surfaces to protrude from or retract into the long sides of the door, and actuate the short-side latch members to protrude from or retract into the short sides of the door.

In a specific embodiment, ends of the connecting ribs are positioned distal to the driving member and respectively connected to the short-side latch members, synchronizing the lateral linear movement of the short-side latch members with the movement of the connecting ribs.

In a specific embodiment, when the plurality of driven assemblies have the plurality of short-side latch members, the short-side latch members are coupled to the connecting rib through a connection portion, synchronizing movement of the short-side latch members with the connecting ribs.

In a specific embodiment, each of the plurality of driven assemblies comprises a driven member and at least one latch member, and wherein the driving member and the driven members are transmission wheels configured to mutually drive each other to transmit power, and wherein, when the driving member rotates, the driven assemblies are synchronously actuated to rotate, allowing the latch member to protrude from or retract into the door.

In a specific embodiment, the driving member comprises a first toothed surface, and each of the driven members comprises a second toothed surface, and wherein the first toothed surface and the second toothed surface are arranged in meshing engagement such that, when the driving member rotates, the driven members are synchronously actuated to rotate.

In a specific embodiment, each of the plurality of driven assemblies comprises two of the driven members, and the two driven members are spaced apart and positioned proximate to short sides of the door.

In a specific embodiment, each of the plurality of driven assemblies comprises at least one long-side latch member, and at least one short-side latch member, with the long-side latch member disposed on long sides of the door, and with the short-side latch member disposed on short sides of the door.

In a specific embodiment, the driving member is disposed in a central region of the door, with the central region defined by a length and a width respectively equal to 0.9 times a length of the non-equilateral rectangular reticle and 0.9 times a width of the non-equilateral rectangular reticle, and a center of the central region is aligned with a geometric center of the door.

The disclosure further provides a non-equilateral rectangular reticle container comprising the latch mechanism.

### BRIEF DESCRIPTION OF THE DRAWINGS

FIG. 1A is a perspective view of a non-equilateral rectangular reticle container (a dual-pod reticle container).

FIG. 1B is an exploded view based on FIG. 1A.

FIG. 2A is a schematic view of a latch mechanism in a locked state according to the first embodiment of the disclosure.

FIG. 2B is a schematic view of the latch mechanism in an unlocked state according to the first embodiment of the disclosure.

FIG. 3A is a schematic view of the latch mechanism in a locked state according to the second embodiment of the disclosure.

FIG. 3B is a schematic view of the latch mechanism in an unlocked state according to the second embodiment of the disclosure.

FIG. 4A is a schematic view of the latch mechanism in a locked state according to the third embodiment of the disclosure.

FIG. 4B is a schematic view of the latch mechanism in an unlocked state according to the third embodiment of the disclosure.

FIG. 5A is a schematic view of the latch mechanism in a locked state according to the fourth embodiment of the disclosure.

FIG. 5B is a schematic view of the latch mechanism in an unlocked state according to the fourth embodiment of the disclosure.

FIG. 6A is a schematic view of the latch mechanism in a locked state according to the fifth embodiment of the disclosure.

FIG. 6B is a schematic view of the latch mechanism in an unlocked state according to the fifth embodiment of the disclosure.

FIG. 7A is a schematic view of the latch mechanism in a locked state according to the sixth embodiment of the disclosure.

FIG. 7B is a schematic view of the latch mechanism in an unlocked state according to the sixth embodiment of the disclosure.

FIG. 8A is a schematic view of the latch mechanism in a locked state according to the seventh embodiment of the disclosure.

FIG. 8B is a schematic view of the latch mechanism in an unlocked state according to the seventh embodiment of the disclosure.

FIG. 9A is a schematic view of the latch mechanism in a locked state according to the eighth embodiment of the disclosure.

FIG. 9B is a schematic view of the latch mechanism in an unlocked state according to the eighth embodiment of the disclosure.

FIG. 10 (PRIOR ART) is a schematic view of a conventional reticle container and latch mechanism.

### DETAILED DESCRIPTION OF THE EMBODIMENTS

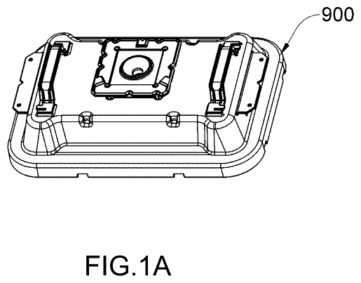

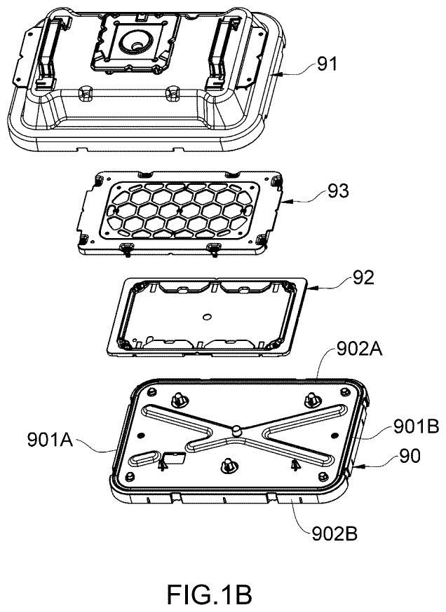

Referring to FIGS. 1A and 1B, there are shown a perspective view and an exploded view of a non-equilateral rectangular reticle container respectively. The non-equilateral rectangular reticle container comprises an outer pod, and an inner pod received in the outer pod. The outer pod comprises a door 90, and a casing 91 engaged with the door 90. The inner pod comprises a baseplate 92, and a cover 93 engaged with the baseplate 92. The disclosure provides a latch mechanism for use in the non-equilateral rectangular reticle container. The latch mechanism is disposed in the door 90 and configured to selectively lock the casing 91 to, or unlock the casing 91 from, the door 90. The latch mechanism comprises a driving member operably engageable with a plurality of driven assemblies. When the driving member rotates, the plurality of driven assemblies are synchronously actuated to undergo reciprocating movement to protrude from or retract into the door 90, such that the plurality of driven assemblies are configured to lock or unlock a side of the door of the non-equilateral rectangular reticle container. The structural features and operation of different embodiments of the latch mechanism are described later.

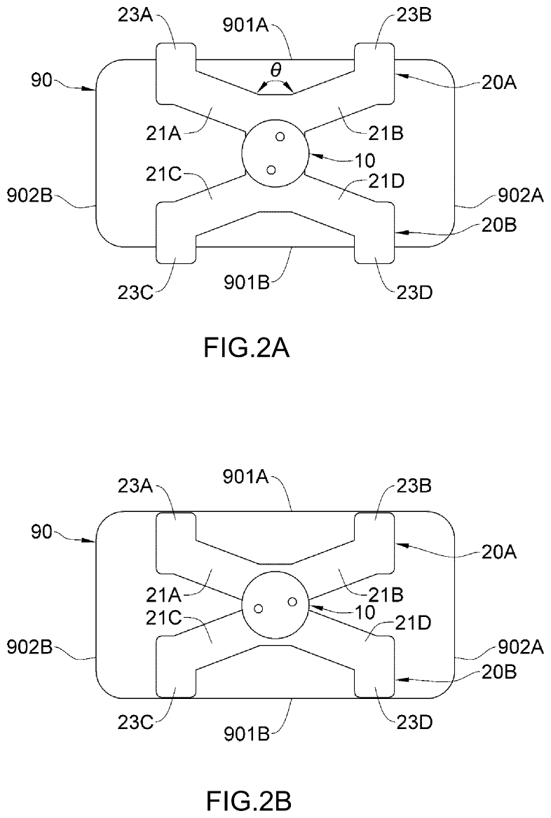

Referring to FIGS. 2A and 2B, there are shown schematic views of a latch mechanism in a locked state and an unlock state according to the first embodiment of the disclosure respectively.

In the first embodiment of the disclosure, a latch mechanism is disposed in the door 90 of a non-equilateral rectangular reticle container. The door 90 has two long sides 901A and 901B and two short sides 902A and 902B. The latch mechanism comprises a driving member 10 and a plurality of driven assemblies. The driving member 10 is disposed in a central region of the door 90 and configured to synchronously drive the plurality of driven assemblies to operate. The central region is defined by a length and a width respectively equal to 0.9 times a length of the non-equilateral rectangular reticle and 0.9 times a width of the non-equilateral rectangular reticle. The center of the central region is aligned with the geometric center of the door 90. Preferably, the driving member 10 is substantially disposed at the geometric center of the door 90.

In the first embodiment, the driving member 10 is a cam, and two of the plurality of driven assemblies are respectively disposed on opposite sides of the door 90 (for example, long sides 901A and 901B) and operably coupled to the driving member 10. The plurality of driven assemblies each comprise at least one driven member 20A, 20B and a latch member 23A-23D. Each driven member 20A, 20B has at least one connecting rib 21A-21D. For example, the connecting ribs 21A and 21B of the driven member 20A extend from the driving member 10 toward the long side 901A to define an angle θ, thereby forming a substantially V-shaped structure. The latch members 23A and 23B are connected to respective ends of the connecting ribs 21A and 21B respectively. Likewise, the connecting ribs 21C and 21D of the driven member 20B extend from the driving member 10 toward the long side 901B to define an angle θ, thereby form a substantially V-shaped structure. The latch members 23C and 23D are connected to respective ends of the connecting ribs 21A and 21B respectively. The latch members 23A-23D are configured to engage with a corresponding receiving portion of the casing. Preferably, the angle θ is a right angle or an obtuse angle, that is, θ is greater than or equal to 90°, such that two of the latch members 23A-23D are spaced apart by a distance while protruding from two positions on one of the long sides 901A and 901B.

In the first embodiment, when the driving member 10 rotates, for example, in the clockwise direction or in the counterclockwise direction, the two driven members 20A, 20B are synchronously actuated to undergo linear movement. As shown in FIG. 2A, the latch members 23A-23D protrude outward from the two long sides 901A and 901B of the door 90 and engage the corresponding receiving portions (not shown) of the casing respectively, thereby locking the casing. As shown in FIG. 2B, the latch members 23A-23D are retracted inward into the long sides 901A and 901B of the door 90 respectively, thereby unlocking the casing. Therefore, the driving member 10 actuates the two driven members 20A, 20B to undergo reciprocating movement, such that at least one of the latch members 23A-23D is capable of locking or unlocking the door 90 of the non-equilateral rectangular reticle container at two positions on at least one of the long sides 901A and 901B.

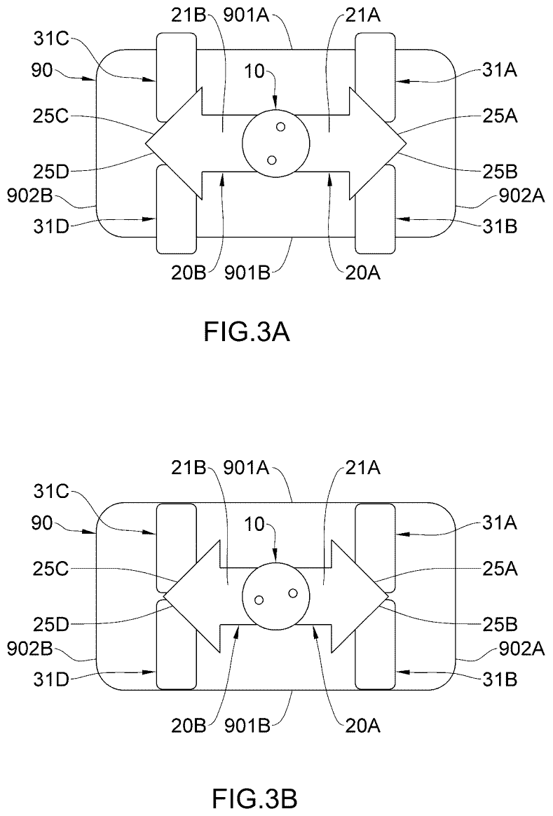

Referring to FIGS. 3A and 3B, there are shown schematic views of the latch mechanism in a locked state and an unlock state according to the second embodiment of the disclosure respectively. In the second embodiment, the latch mechanism is disposed in the door 90 of the non-equilateral rectangular reticle container. The door 90 has two long sides 901A and 901B and two short sides 902A and 902B. The latch mechanism comprises the driving member 10 and the plurality of driven assemblies. The plurality of driven assemblies are disposed on two opposite short sides 902A and 902B of the door 90 respectively. The plurality of driven assemblies each comprise a driven member that comprises a driven member 20A and 20B and at least one latch member 31A-31D. The driven members 20A and 20B have connecting ribs 21A and 21B respectively, with one end connected to the driving member 10, and with the other end connected to at least one latch member 31A-31D. The latch members are disposed on the long sides 901A and 901B of the door 90. More particularly, the connecting rib 21A of the driven member 20A extends from the driving member 10 toward the short side 902A by a length and is configured to abut against the latch members 31A and 31B. Likewise, the connecting rib 21B of the driven member 20B extends from the driving member 10 toward the short side 902B by a length and is configured to abut against the latch members 31C and 31D. When the driving member 10 rotates, the driven members 20A and 20B are synchronously actuated, allowing the connecting ribs 21A and 21B to undergo lateral linear movement toward the short sides 902A and 902B respectively. The connecting rib 21A moving toward the short side 902A simultaneously pushes the latch member 31A to move longitudinally toward the long side 901A and pushes the latch member 31B to move longitudinally toward the long side 901B. The connecting rib 21B moving toward the short side 902B simultaneously pushes the latch member 31C to move longitudinally toward the long side 901A and pushes the latch member 31D to move longitudinally toward the long side 901B. Therefore, the driving member 10 actuates the two driven member 20A, 20B to undergo reciprocating movement, such that the latch members 31A-31D synchronously protrude from or retract into the door 90, thereby locking or unlocking two positions on the long sides 901A and 901B of the door 90 of the non-equilateral rectangular reticle container.

In the second embodiment, the connecting rib 21A of the driven member 20A has two opposite inclined surfaces 25A and 25B, and the connecting rib 21B of the driven member 20B has two opposite inclined surfaces 25C and 25D, allowing the latch members 31A-31D to abut against the inclined surfaces 25A-25D respectively. The connecting rib 21A of the driven member 20A has two inclined surfaces 25A and 25B, allowing the latch member 31A to abut against the inclined surface 25A, and allowing the latch member 31B to abut against the inclined surface 25B. The connecting rib 21B of the driven member 20B has two opposite inclined surface 25C and 25D, allowing the latch member 31C to abut against the inclined surface 25C, and allowing the latch member 31D to abut against the inclined surface 25D. The latch members 31A and 31B are actuated by the connecting rib 21A to slide along the inclined surfaces 25A and 25B respectively. The latch members 31C and 31D are actuated by the connecting rib 21B to slide along the inclined surfaces 25C and 25D respectively. When the driving member 10 rotates, the connecting ribs 21A and 21B of the driven members 20A and 20B are synchronously actuated to undergo lateral linear movement toward the short sides 902A and 902B respectively. The lateral movement of the connecting ribs 21A and 21B causes the latch members 31A-31D to slide along the differently oriented sides 25A-25D respectively. Finally, the latch members 31A-31D longitudinally move toward the long sides 901A and 901B of the door 90, protruding therefrom so as to lock as shown in FIG. 3A, or retracting therein so as to unlock as shown in FIG. 3B.

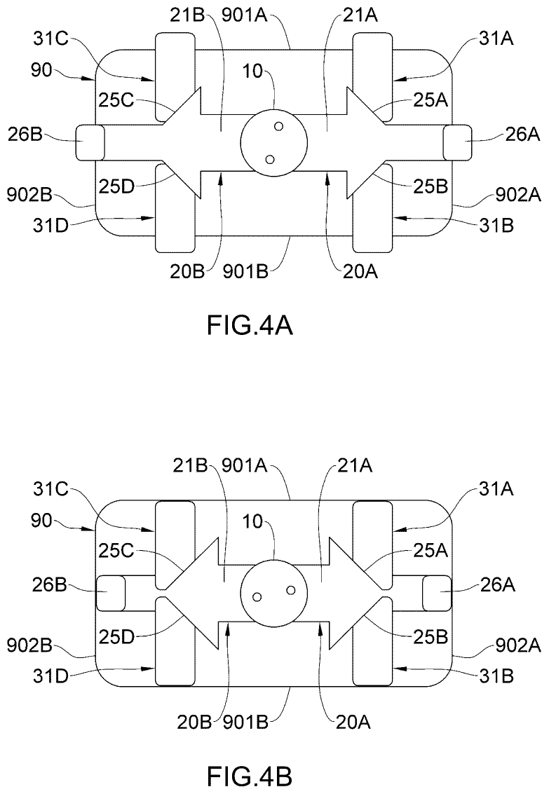

Referring to FIGS. 4A and 4B, there are shown schematic views of the latch mechanism in a locked state and an unlock state according to the third embodiment of the disclosure respectively. Only the differences, not the similarities, between the third and second embodiments are described below. The second embodiment is directed to locking and unlocking the long sides 901A and 902B of the door 90. The third embodiment is directed to locking and unlocking the long sides 901A and 902B and the short sides 902A and 902B of the door 90 simultaneously.

In the third embodiment, the plurality of driven assemblies each exhibit structural features capable of locking long sides and short sides simultaneously. More particularly, the plurality of driven assemblies each comprise the driven members 20A and 20B, at least one of the long-side latch members 31A-31D, and at least one of short-side latch members 26A and 26B. The connecting rib 21A of the driven member 20A extends a distance from the driving member 10 toward the short side 902A. The long-side latch members 31A and 31B are disposed on the long sides 901A and 901B of the door 90 respectively, with the short-side latch member 26A disposed on the short side 902A of the door 90. The connecting rib 21B of the driven member 20B extends a distance from the driving member 10 toward the short side 902B. The long-side latch members 31C and 31D are disposed on the long sides 901A and 901B of the door 90 respectively, with the short-side latch member 26B disposed on the short side 902B of the door 90. When the driving member 10 rotates, the driven members 20A and 20B are synchronously actuated. Thus, the connecting rib 21A of the driven member 20A undergoes lateral linear movement to synchronously push the long-side latch member 31A toward the long side 901A of the door, the long-side latch member 31B toward the long side 901B of the door, and the short-side latch member 26A toward the short side 902A of the door. Likewise, the connecting rib 21B of the driven member 20B undergoes lateral linear movement to synchronously push the long-side latch member 31C toward the long side 901A of the door, the long-side latch member 31D toward the long side 901B of the door, and the short-side latch member 26B toward the short side 902B of the door. Therefore, in the third embodiment, when the driving member 10 rotates (for example, clockwise rotation or counterclockwise rotation defines a locked state or an unlocked state), the connecting ribs 21A and 21B of the driven members 20A and 20B undergo lateral linear movement, such that the long-side latch members 31A-31D and the short-side latch members 26A and 26B protrude from or retract into the long sides 901A and 901B and the short sides 902A and 902B of the door 90 simultaneously and respectively, thereby locking or unlocking side positions of the door 90 of the non-equilateral rectangular reticle container. The long-side latch members 31A-31D and short-side latch members 26A and 26B are configured to engage the corresponding receiving portion of the casing so as to securely connect the long sides 901A and 901B and the short sides 902A and 902B of the door with the casing.

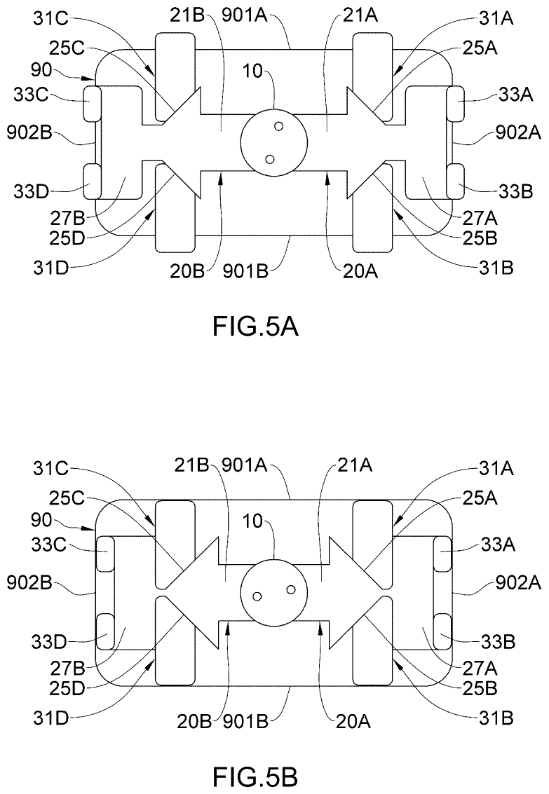

Referring to FIGS. 5A and 5B, there are shown schematic views of the latch mechanism in a locked state and an unlock state according to the fourth embodiment of the disclosure respectively. Only the differences, not the similarities, between the fourth and third embodiments are described below. In the third embodiment, the driven members 20A and 20B have a single short-side latch member 26A and 26B respectively, and the connecting ribs 21A and 21B of the driven members 20A and 20B have ends which are positioned distal to the driving member 10 and respectively connected to the short-side latch members 26A and 26B, thereby synchronizing the lateral linear movement of the short-side latch members with the movement of the connecting ribs. In the fourth embodiment, the driven member 20A has the plurality of short-side latch members 33A-33B, and the driven member 20B has the short-side latch members 33C-33D.

In the fourth embodiment, the driven member 20A and 20B further comprises a connection portion 27A and 27B respectively, which serve as connecting structures between the plurality of short-side latch members 33A-33D and the connecting ribs 21A and 21B. More particularly, the connecting rib 21A of the driven member 20A is coupled to the short-side latch members 33A and 33B through the connection portion 27A. The short-side latch members 33A and 33B are spaced apart and disposed on one side of the connection portion 27A, and are oriented toward the short side 902A of the door 90. Likewise, the connecting rib 21B of the driven member 20B is coupled to the short-side latch members 33C and 33D through the connection portion 27B. The short-side latch members 33C and 33D are spaced apart and disposed on one side of the connection portion 27B, and are oriented toward the short side 902B of the door 90. When the driving member 10 rotates (for example, clockwise rotation or counterclockwise rotation defines a locked state or an unlocked state), the connecting ribs 21A and 21B of the driven members 20A and 20B undergo lateral linear movement, thereby synchronizing the lateral linear movement of the short-side latch members 33A-33D with the movement of connecting ribs 21A and 21B. The corresponding receiving portions of the casing corresponds in number to the short-side latch members, such that the short sides 902A and 902B of the door 90 can be firmly connected to the casing.

In the first to fourth embodiments, the driven members each further comprise an elastic member, such as a spring or an elastic structural component, which continuously applies a biasing force to the driven member, thereby forcing the driven member to move toward the long sides and short sides of the door 90. The elastic member enables the reticle container to remain in a locked state, thereby not only preventing malfunction of an unlocking mechanism of the load port, but also further protecting the reticle.

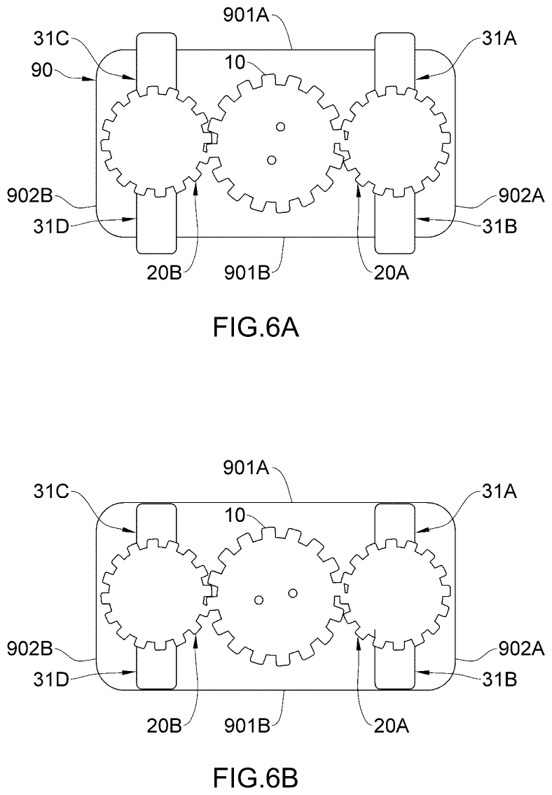

Referring to FIGS. 6A and 6B, there are shown schematic views of the latch mechanism in a locked state and an unlock state according to the fifth embodiment of the disclosure respectively. Only the differences, not the similarities, between the fifth and second embodiments are described below. In the fifth embodiment, the connecting ribs 21A and 21B of the second embodiment are replaced with transmission wheels. More particularly, in the fifth embodiment, the latch mechanism comprises the driving member 10 and the plurality of driven assemblies. The driving member 10 is disposed in a central region of the door 90 and configured to synchronously drive the plurality of driven assemblies to operate. The plurality of driven assemblies comprise the driven members 20A and 20B and latch members 31A-31D. The driving member 10 and the plurality of driven members 20A and 20B are transmission wheels configured to mutually drive each other to transmit power. When the driving member 10 rotates, the driven members 20A and 20B are synchronously driven to rotate, thereby causing the latch members 31A-31D to protrude from or retract into the door.

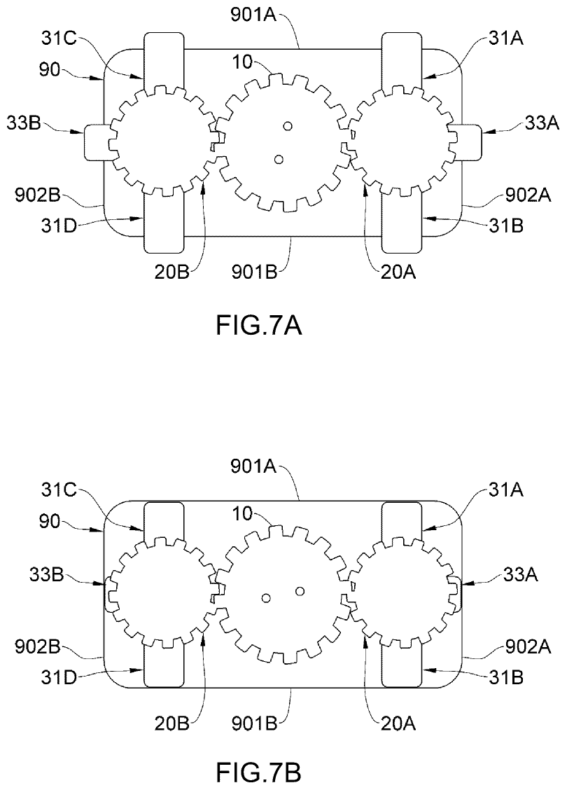

Referring to FIGS. 7A and 7B, there are shown schematic views of the latch mechanism in a locked state and an unlock state according to the sixth embodiment of the disclosure respectively. Only the differences, not the similarities, among the sixth, fifth, and third embodiments are described below. In the fifth embodiment, locking and unlocking are performed at the long sides 901A and 902B of the door 90. In the sixth embodiment, locking and unlocking are simultaneously performed at the long sides 901A and 902B and the short sides 902A and 902B of the door 90. In the sixth embodiment, the connecting ribs 21A and 21B of the third embodiment are replaced with transmission wheels. When the driving member 10 rotates (for example, clockwise rotation or counterclockwise rotation defines a locked state or an unlocked state), the plurality of driven members 20A and 20B are synchronously actuated, thereby allowing the long-side latch members 31A-31D and the short-side latch members 33A and 33B to protrude from or retract into the door 90.

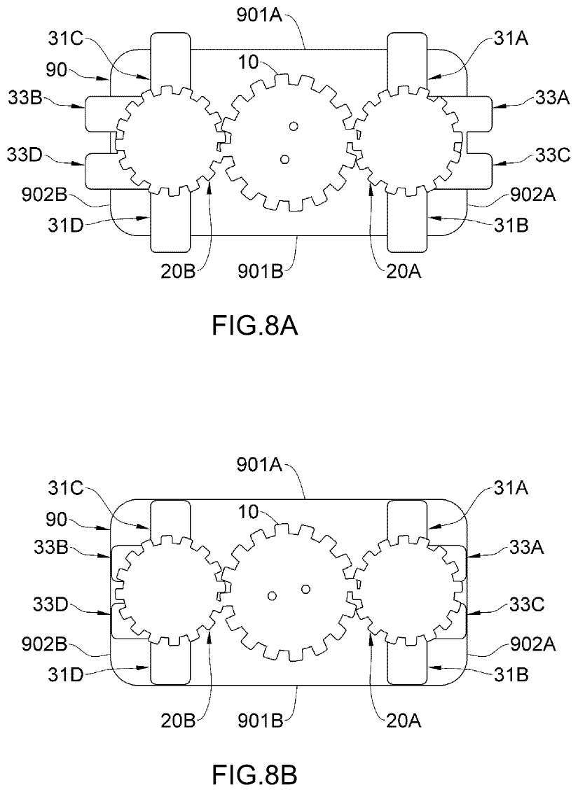

Referring to FIGS. 8A and 8B, there are shown schematic views of the latch mechanism in a locked state and an unlock state according to the seventh embodiment of the disclosure respectively. Only the differences, not the similarities, among the seventh, sixth, and fourth embodiments are described below. In the sixth embodiment, the driven members 20A and 20B each have a single the short-side latch members 33A and 33B respectively. In the seventh embodiment, the driven members 20A and 20B each have the plurality of short-side latch members 33A-33B and 33C-33D respectively. In the seventh embodiment, the connecting ribs 21A and 21B and connection portions of the fourth embodiment are replaced with transmission wheels. When the driving member 10 rotates (for example, clockwise rotation or counterclockwise rotation defines a locked state or an unlocked state), the plurality of driven members 20A and 20B are synchronously actuated, thereby allowing the long-side latch members 31A-31D and the short-side latch members 33A-33D to protrude from or retract into the door 90.

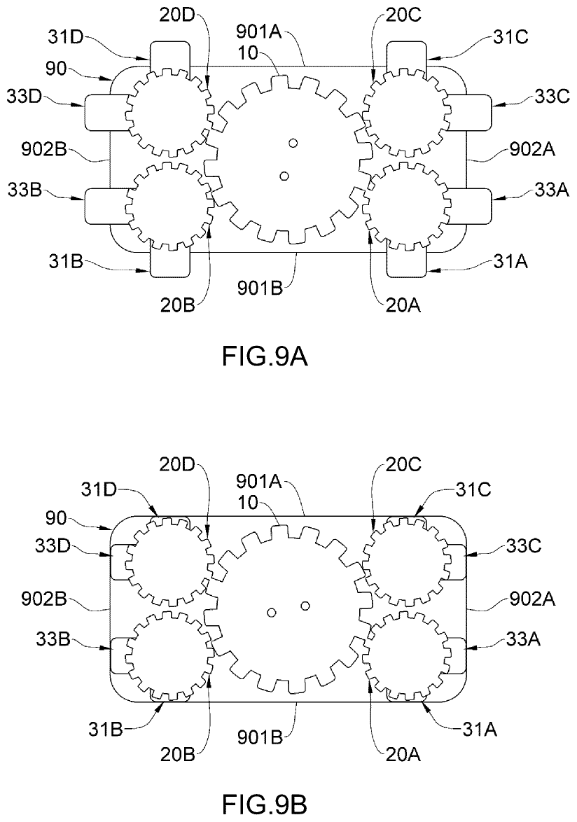

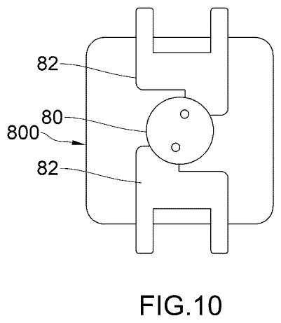

Referring to FIGS. 9A and 9B, there are shown schematic views of the latch mechanism in a locked state and an unlock state according to the eighth embodiment of the disclosure respectively. In the eighth embodiment, the driving member 10 and the plurality of driven members 20A-20D are transmission wheels configured to mutually drive each other to transmit power. The door 90 has two long sides 901A and 901B and two short sides 902A and 902B. The driven members 20A-20D of the plurality of driven assemblies are positioned proximate to four corners of the door 90 respectively and configured not to interfere with each other. The driven members 20A and 20C are positioned on one side of the driving member 10, and the driven members 20B and 20D are positioned on the other side of the driving member 10. The driven members 20A-20D each comprise one long-side latch member and one short-side latch member.

More particularly, the latch mechanism comprises the driving member 10 and the plurality of driven assemblies. The plurality of driven assemblies each comprise two of the driven members 20A-20D, two of the long-side latch members 31A-31D, and two of the short-side latch members 33A-33D. The plurality of driven assemblies positioned on one side of the driving member 10 comprise two driven members 20A and 20C spaced apart and positioned proximate to the short side 902A of the door. The driven member 20A is connected to the long-side latch members 31A and short-side latch member 33A, allowing the long-side latch member 31A to be disposed on the long side 901B, and allowing the short-side latch member 33A to be disposed on the short side 902A. The driven member 20C is connected to the long-side latch members 31C and short-side latch member 33C, allowing the long-side latch member 31C to be disposed on the long side 901A, and allowing the short-side latch member 33C to be disposed on the short side 902A.

More particularly, the plurality of driven assemblies positioned on the other side of the driving member 10 comprise two driven members 20B and 20D spaced apart and positioned proximate to the short side 902B of the door. The driven member 20B is connected to the long-side latch member 31B and the short-side latch member 33B, allowing the long-side latch member 31B to be disposed on the long side 901B, and allowing the short-side latch member 33B to be disposed on the short side 902B. The driven member 20D is connected to the long-side latch member 31D and the short-side latch member 33D, allowing the long-side latch member 31D to be disposed on the long side 901A, and allowing the short-side latch member 33C to be disposed on the short side 902B.

The rotation of the driving member 10 synchronously actuates four driven members 20A-20D to rotate, thereby causing the four short-side latch members 33A-33D to protrude outward from the short sides 902A and 902B of the door 90 or retract inward into the short sides 902A and 902B of the door 90, and simultaneously causing the four long-side latch members 31A-31D to protrude outward from the long sides 901A and 901B of the door 90 or retract inward into the long sides 901A and 901B of the door 90, respectively, to lock or unlock the door 90.

In the fifth to eighth embodiments, the driving member and the plurality of driven members are preferably transmission wheels. For instance, the driving member comprises a first toothed surface, and the driven members each comprise a second toothed surface. The first toothed surface and the second toothed surface are arranged in meshing engagement such that, when the driving member rotates, the driven members are synchronously actuated to rotate under the meshing force.

In the fifth to eighth embodiments, the latch members each further comprise an elastic member, such as a spring or an elastic structural component, which continuously applies a biasing force to the latch members, thereby forcing the latch members to move toward the long sides and short sides of the door 90. The clastic member enables the reticle container to remain in a locked state, thereby not only preventing malfunction of an unlocking mechanism of the load port, but also further protecting the reticle.

What is claimed is:

1. A latch mechanism, adapted for a door of a non-equilateral rectangular reticle container, comprising:
a driving member disposed at the door;
a plurality of driven assemblies respectively abutting against the driving member, wherein, when the driving member rotates, the plurality of driven assemblies are synchronously actuated to undergo reciprocating movement to protrude from or retract into the door, such that at least one of the plurality of driven assemblies is configured to lock or unlock a side of the door of the non-equilateral rectangular reticle container.

2. The latch mechanism of claim 1, wherein the plurality of driven assemblies are configured to lock or unlock long sides of the door of the non-equilateral rectangular reticle container.

3. The latch mechanism of claim 1, wherein the plurality of driven assemblies are respectively disposed on opposite sides of the door and operably coupled to the driving member, and each of the plurality of driven assemblies comprises a driven member and a latch member, the driven member having a connecting rib, one end of the connecting rib connected to the driving member and the other end of the connecting rib connected to the latch member, such that, when the driving member rotates, the driven members are synchronously actuated, allowing the latch members to protrude from or retract into the door.

4. The latch mechanism of claim 3, wherein, when the driving member rotates, the driven members are synchronously actuated, allowing the connecting ribs to undergo lateral linear movement and push the latch members to move longitudinally toward the sides of the door, allowing the latch members to protrude from or retract into the door.

5. The latch mechanism of claim 3, wherein each of the connecting ribs has two opposite inclined surfaces, and the latch members are actuated by the connecting ribs to slide along the inclined surfaces respectively, allowing the latch members to protrude from or retract into a lateral side of the door.

6. The latch mechanism of claim 1, wherein each of the plurality of driven assemblies comprises a connecting rib, at least one long-side latch member, and at least one short-side latch member, one end of the connecting rib connected to the driving member, with the long-side latch member disposed on long sides of the door, and with the short-side latch member disposed on short sides of the door, wherein, when the driving member rotates, the plurality of driven assemblies are synchronously actuated to cause the connecting ribs to undergo lateral linear movement to synchronously push the long-side latch member toward the long sides of the door and the short-side latch member toward the short sides of the door, allowing the long-side latch member and the short-side latch member to protrude from or retract into the door simultaneously.

7. The latch mechanism of claim 6, wherein each of the connecting ribs has two opposite inclined surfaces corresponding in position to the long-side latch members, and ends of the connecting ribs are positioned distal to the driving member and respectively connected to the short-side latch members, and wherein the connecting ribs actuate the long-side latch members to slide along the inclined surfaces to protrude from or retract into the long sides of the door, and actuate the short-side latch members to protrude from or retract into the short sides of the door.

8. The latch mechanism of claim 6, wherein ends of the connecting ribs are positioned distal to the driving member and respectively connected to the short-side latch members, synchronizing the lateral linear movement of the short-side latch members with the movement of the connecting ribs.

9. The latch mechanism of claim 6, wherein, when the plurality of driven assemblies have the plurality of short-side latch members, the short-side latch members are coupled to the connecting rib through a connection portion, synchronizing movement of the short-side latch members with the connecting ribs.

10. The latch mechanism of claim 1, wherein each of the plurality of driven assemblies comprises a driven member and at least one latch member, and wherein the driving member and the driven members are transmission wheels configured to mutually drive each other to transmit power, and wherein, when the driving member rotates, the driven members are synchronously actuated to rotate, allowing the latch member to protrude from or retract into the door.

11. The latch mechanism of claim 10, wherein the driving member comprises a first toothed surface, and each of the driven members comprises a second toothed surface, and wherein the first toothed surface and the second toothed surface are arranged in meshing engagement such that, when the driving member rotates, the driven members are synchronously actuated to rotate.

12. The latch mechanism of claim 10, wherein each of the plurality of driven assemblies comprises two of the driven members, and the two driven members are spaced apart and positioned proximate to short sides of the door.

13. The latch mechanism of claim 1, wherein each of the plurality of driven assemblies comprises a driven member, at least one long-side latch member, and at least one short-side latch member, with the long-side latch member disposed on long sides of the door, and with the short-side latch member disposed on short sides of the door, wherein the driving member and the driven members are transmission wheels configured to mutually drive each other to transmit power, and wherein, when the driving member rotates, the driven members are synchronously actuated to rotate, allowing the long-side latch member and the short-side latch member to protrude from or retract into the door.

14. The latch mechanism of claim 1, wherein the driving member is disposed in a central region of the door, with the central region defined by a length and a width respectively equal to 0.9 times a length of the non-equilateral rectangular reticle and 0.9 times a width of the non-equilateral rectangular reticle, and a center of the central region is aligned with a geometric center of the door.

15. A non-equilateral rectangular reticle container having the latch mechanism of claim 1.
